(19) United States
(12) Patent Application Publication
(10) Pub. No.: US 2020/0152252 A1
(43) Pub. Date: May 14, 2020

(54) SPIN-ORBIT TORQUE MAGNETORESISTIVE RANDON ACCESS MEMORY AND METHOD AND APPARATUS FOR WRITING THE SAME

(71) Applicant: Institute of Microelectronics, Chinese Academy of Sciences, Beijing (CN)

(72) Inventors: Meiyin YANG, Beijing (CN); Jun LUO, Beijing (CN)

(73) Assignee: Institute of Microelectronics, Chinese Academy of Sciences

(21) Appl. No.: 16/452,035

(22) Filed: Jun. 25, 2019

(30) Foreign Application Priority Data
Nov. 9, 2018 (CN) 201811333178.2

(51) Int. Cl. G11C 11/16; H01L 43/10; H01L 43/04; H01L 27/22; H01F 10/32

(52) U.S. Cl. CPC G11C 11/1675; G11C 11/161; H01L 43/10; H01L 43/04; G11C 11/18; H01F 10/3286; H01F 10/3254; H01F 10/329; H01L 27/222

(57) ABSTRACT

A spin-orbit torque magnetoresistive random access memory, and a method and an apparatus for writing the same. A magnetoresistive tunnel junction is provided on a spin-orbit coupling layer. In a case that a current is applied to the spin-orbit coupling layer, a spin current is generated in the spin-orbit coupling layer, so that a magnetic moment in the magnetoresistive tunnel junction is oriented into a plane of the spin-orbit coupling layer. At such time, there is a temperature difference between one end of the magnetoresistive tunnel junction and another end of the magnetoresistive tunnel junction. An deterministic switching of the magnetic moment is achieved under the temperature difference, and a switching direction can be controlled based on the direction of the current direction or the direction of the temperature difference. Thereby, the deterministic switching of the magnetic moment is achieved in the SOT-MRAM.

The present disclosure claims the priority to Chinese patent application No. 201811333178.2 titled “SPIN-ORBIT TORQUE MAGNETORESISTIVE RANDOM ACCESS MEMORY AND METHOD AND APPARATUS FOR WRITING THE SAME,” filed on Nov. 9, 2018, with the China National Intellectual Property Administration, which is incorporated herein by reference in its entirety.

### FIELD

The present disclosure relates to the field of semiconductor devices and manufacture thereof, and in particular, to a spin-orbit torque magnetoresistive random access memory, and a method and an apparatus for writing the spin-orbit torque magnetoresistive random access memory.

### BACKGROUND

With continuous development of memory technology and electronic technology, random access memories have been widely used, and may be independent of or integrated into a device using the random access memories, such as a processor, an application specific integrated circuit, or a system on chip.

Spin-orbit torque magnetoresistive random access memory (SOT-MRAM) is a magnetic random access memory that performs random access by using magnetic moment switching. It has advantages of high-speed reading and writing, high integration, and unlimited times of repeated writings. In the SOT-MRAM, a spin current is generated through spin-orbit coupling, and thereby a magnetic moment of a magnet is induced to switch. A switching direction of the magnetic moment under a current is random, while an effective data access requires a deterministic switching of the magnetic moment. A research focus of the SOT-MRAM is how to achieve the deterministic switching of the magnetic moment.

### SUMMARY

In view of this, an object of the present disclosure is to provide a spin-orbit torque magnetoresistive random access memory, and a method and an apparatus for writing the spin-orbit torque magnetoresistive random access memory, so as to realize a deterministic switching of a magnetic moment in a memory.

To achieve the above object, following technology solutions are provided according to the present disclosure.

A spin-orbit torque magnetoresistive random access memory is provided, including:

a spin-orbit coupling layer;

a magnetoresistive tunnel junction on the spin-orbit coupling layer, where the magnetoresistive tunnel junction includes a first magnetic layer, a tunneling layer, and a second magnetic layer, which are stacked in sequence from bottom to top, and the first magnetic layer and the second magnetic layer have perpendicular anisotropy;

where for data writing of the memory, a current is injected into the spin-orbit coupling layer, and a temperature of the magnetoresistive tunnel junction is controlled to cause a temperature difference between one end of the magnetoresistive tunnel junction and another end of the magnetoresistive tunnel junction.

Optionally, the temperature difference is along a direction of the current.

Optionally, the spin-orbit coupling layer is a metal layer, an antiferromagnetic layer or a topological insulator layer.

Optionally, the metal layer is made of Ta, Pt, W, Hf, Ir, CuBi, Culr or AuW.

Optionally, the first magnetic layer and the second magnetic layer are made of Co, Fe, CoFeB or FePt.

Optionally, that the temperature of the magnetoresistive tunnel junction is controlled to cause the temperature difference between the one end of the magnetoresistive tunnel junction and the another end of the magnetoresistive tunnel junction, includes:

heating a region at the one end of the magnetoresistive tunnel junction, to cause the temperature difference between the one end of the magnetoresistive tunnel junction and the another end of the magnetoresistive tunnel junction.

Optionally, a manner of the heating is Joule heating or laser heating.

A method for writing the spin-orbit torque magnetoresistive random access memory, where the memory includes a spin-orbit coupling layer, and a magnetoresistive tunnel junction on the spin-orbit coupling layer; where the magnetoresistive tunnel junction includes a first magnetic layer, a tunneling layer, and a second magnetic layer, which are stacked in sequence from bottom to top, and the first magnetic layer and the second magnetic layer are anisotropic in a vertical direction; and where the method includes:

injecting a current into the spin-orbit coupling layer, and controlling a temperature of the magnetoresistive tunnel junction to cause a temperature difference between one end of the magnetoresistive tunnel junction and another end of the magnetoresistive tunnel junction.

An apparatus for writing the spin-orbit torque magnetoresistive random access memory, where the memory includes a spin-orbit coupling layer, and a magnetoresistive tunnel junction on the spin-orbit coupling layer; where the magnetoresistive tunnel junction includes a first magnetic layer, a tunneling layer, and a second magnetic layer, which are stacked in sequence from bottom to top, and the first magnetic layer and the second magnetic layer are anisotropic in a vertical direction; and where the apparatus includes:

a current source, configured to inject a current into the spin-orbit coupling layer; and

a temperature controller, configured to control a temperature of the magnetoresistive tunnel junction to cause a temperature difference between one end of the magnetoresistive tunnel junction and another end of the magnetoresistive tunnel junction.

Optionally, the temperature controller is configured to heat a region at the one end of the magnetoresistive tunnel junction.

Optionally, the temperature controller is a laser heater or a Joule heater.

The spin-orbit torque magnetoresistive random access memory, and the method and the apparatus for writing the spin-orbit torque magnetoresistive random access memory are provided according to the present disclosure. A magnetoresistive tunnel junction is provided on the spin-orbit coupling layer. In a case that the current is injected into the spin-orbit coupling layer, a spin current is generated in the spin-orbit coupling layer, so that a magnetic moment of the magnetoresistive tunnel junction is oriented into a plane of the spin-orbit coupling layer. At such time, there is the temperature difference between the one end of the magnetoresistive tunnel junction and the another end of the magnetoresistive tunnel junction. A deterministic switching of the magnetic moment is achieved under the temperature difference, and a switching direction can be controlled based on the direction of the current or a direction of the temperature difference. Thereby, the deterministic switching of the magnetic moment is achieved in the SOT-MRAM.

### BRIEF DESCRIPTION OF THE DRAWINGS

For clearer illustration of the technical solutions according to embodiments of the present disclosure or conventional techniques, hereinafter are briefly described the drawings to be applied in embodiments of the present disclosure or conventional techniques. Apparently, the drawings in the following descriptions are only some embodiments of the present disclosure, and other drawings may be obtained by those skilled in the art based on the provided drawings without creative efforts.

FIG. 1 is a schematic diagram of a top view of a spin-orbit torque magnetoresistive random access memory according to an embodiment of the present disclosure; and

FIG. 2 is a schematic diagram of a cross-sectional structure along an AA direction in FIG. 1.

### DETAILED DESCRIPTION

For making the objects, features and advantages of the present disclosure clear and easy to understand, the embodiments of the present disclosure are described in detail hereinafter in conjunction with the drawings.

In the following description, numerous specific details are illustrated in order to provide a thorough understanding of the disclosure. The disclosure may also be carried out in ways other than those described herein. A person skilled in the art can make a similar deduction without departing from the spirit of the disclosure, and thus the disclosure is not limited by the specific embodiments disclosed hereinafter.

Further, the present disclosure is described in detail in conjunction with the schematic diagrams. In detailed description of the embodiments of the present disclosure, for the convenience of description, the cross-sectional diagram showing the structure of the apparatus may not be partially enlarged according to the general proportion. The schematic diagrams are only examples, which are not intended to limit the scope of the disclosure. Furthermore, it should include the three-dimensional dimensions of length, width and depth in the practical production.

As described in the background, a magnetic random access memory that performs random access through magnetic moment switching has advantages of high-speed reading and writing, high integration, and unlimited times of repeated writings. The spin-orbit coupling is used to generate a spin current and thereby induce a magnetic moment to switch, and a switching direction of the magnetic moment is random under a current. A data can be effectively accessed only when the deterministic switching of the magnetic moment is effectively controlled, so as to facilitate integration and industrialization of the spin-orbit torque magnetoresistive random access memory.

In view of the above, a spin-orbit torque magnetoresistive random access memory is provided according to the present disclosure, which is SOT-MRAM. A magnetoresistive tunnel junction is provided on a spin-orbit coupling layer. In a case that a current is applied to the spin-orbit coupling layer, a spin current is generated in the spin-orbit coupling layer, so that the magnetic moment in the magnetoresistive tunnel junction is oriented to the plane of the spin-orbit coupling layer. At this time, there is a temperature difference between one end of the magnetoresistive tunnel junction and another end of the magnetoresistive tunnel junction in the current direction, the deterministic switching of the magnetic moment is realized under the action of the temperature difference, and the switching direction can be controlled by the current direction or the temperature difference direction, thereby realizing the deterministic switching of the magnetic moment in the SOT-MRAM.

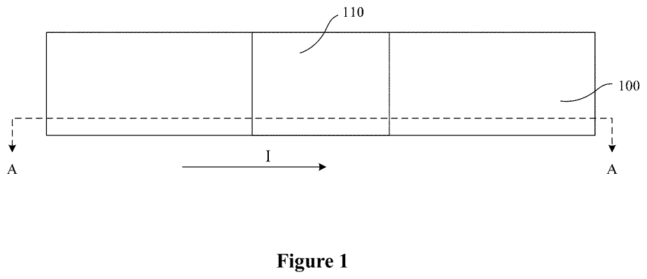

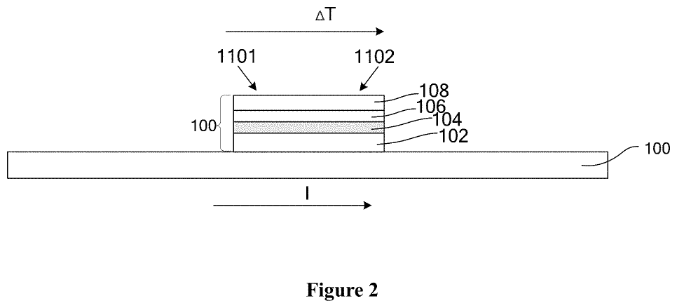

Reference is made to FIGS. 1 and 2. A SOT-MRAM includes a spin-orbit coupling layer 100, and a magnetoresistive tunnel junction 110 on the spin-orbit coupling layer 100.

The magnetoresistive tunnel junction 110 includes a first magnetic layer 102, a tunneling layer 104, and a second magnetic layer 106, which are stacked in sequence from bottom to top. The first magnetic layer and the second magnetic layer are anisotropic in a vertical direction.

For data writing of the memory, a current I is injected into the spin-orbit coupling layer 100, and a temperature of the magnetoresistive tunnel junction 110 is controlled to cause a temperature difference between one end 1101 of the magnetoresistive tunnel junction and another end 1102 of the magnetoresistive tunnel junction along a direction of the current I.

In an embodiment of the present disclosure, the spin-orbit coupling layer 100 is made of a material with a spin-orbit coupling effect. Generally, the spin-orbit coupling layer 100 may be a metal layer with the spin coupling effect, an antiferromagnetic layer with the spin coupling effect, or a topological insulator layer with the spin coupling effect. Preferably, a material with a large spin-orbit coupling strength may be selected. The material of the metal layer may be, for example, Ta, Pt, W, Hf, Ir, CuBi, Culr, or AuW. The material of the topological insulator layer may be, for example, BiSn, SnTe, BiSe, and the like, or may be another compound of IVA, VA and VIA families. The material of the antiferromagnetic layer may be, for example, IrMn and PtMn.

In the present disclosure, the magnetoresistive tunnel junction 110 is located on the spin-orbit coupling layer 100. Referring to FIG. 1, the direction of the current in the spin-orbit coupling layer 100, for convenience of description, is recorded as a length direction of the spin-orbit coupling layer. The magnetoresistive tunnel junction 110 may be arranged in the middle of the spin-orbit coupling layer 100, and may be symmetrically arranged along the center line of the spin-orbit coupling layer 100 along the direction of the current. In a specific application, a shape and a size of the magnetoresistive tunnel junction 110 may be set according to requirements. In a preferred embodiment, the shape of the magnetoresistive tunnel junction 110 may be a bar, and a width of the bar may be substantially identical to that of the spin-orbit coupling layer 100.

It should be noted that the current I is a current injected for inducing the magnetic moment in the magnetoresistive tunnel junction 110 to switch, that is, a current injected for writing information. The current is injected into the spin-orbit coupling layer 100. Herein the direction of the current I refers to a direction of I or a direction reverse to the direction of I.

In an embodiment of the present disclosure, the magnetoresistive tunnel junction 110 includes a first magnetic layer 102, a tunneling layer 104, and a second magnetic layer 106, which are stacked in sequence from bottom to top. The first magnetic layer 102 and the second magnetic layer 106 are made of a ferromagnetic material with perpendicular anisotropy. The ferromagnetic material may be an elementary ferromagnetic material, an alloy ferromagnetic material, or a metal oxide with magnetism, for example, a magnetically hard material such as Co, Fe, CoFeB or FePt. The first magnetic layer 102 and the second magnetic layer 106 may be made of same or different materials according to specific requirements.

The tunneling layer 104 is located between the first magnetic layer 102 and the second magnetic layer 106, and may be made of an insulating material, such as aluminum oxide, magnesium oxide or cerium oxide.

Further, the magnetoresistive tunnel junction 110 may further includes a pinning layer 108 above the second magnetic layer 106. The pinning layer 108 is configured to fix a magnetization direction. For convenience of description, the pinning layer 108 above the second magnetic layer 106 may be denoted as a top pinning layer, and a bottom pinning layer may further be provided between the first magnetic layer 102 and the magnetoresistive tunnel junction 110. The pinning layer may be made of, for example, an artificial antiferromagnet of a CoPt multilayer film.

The structure of the SOT-MRAM according to the embodiment of the present disclosure has been described above. It should be understood that, in a specific application, the SOT-MRAM may further include other necessary components, such as an electrode and a protective layer on the magnetoresistive tunnel junction 110.

Based on the above structure of the SOT-MRAM, in case of data writing, a current is injected into the spin-orbit coupling layer, and a temperature of the magnetoresistive tunnel junction is controlled to cause a temperature difference between one end of the magnetoresistive tunnel junction and another end of the magnetoresistive tunnel junction After the current is injected into the spin-orbit coupling layer, spin-up or spin-down electrons in the spin-orbit coupling layer are accumulated at an interface between the spin-orbit coupling layer 100 and the first magnetic layer 102 due to the spin Hall effect or the Rashba effect. The spin current diffuses into the first magnetic layer 102, so that the magnetic moment in the magnetoresistive tunnel junction is oriented into the plane of the spin-orbit coupling layer. At such time, there is a temperature difference ΔT between one end of the magnetoresistive tunnel junction and another end of the magnetoresistive tunnel junction. In a case that the temperature difference reaches a certain value, the deterministic switching of the magnetic moment is achieved under the temperature difference ΔT. Thereby, the deterministic switching of the magnetic moment is achieved in the SOT-MRAM

In a specific application, the switching direction may be controlled based on the direction of the current or a direction of the temperature difference. In a case that the direction of the current is fixed and the temperature of one end of the magnetoresistive tunnel junction is greater than that of another end of the magnetoresistive tunnel junction, the magnetic moment is switched into one direction. On the contrary, in a case that the temperature of the one end of the magnetoresistive tunnel junction is lower than that of the another end of the magnetoresistive tunnel junction, the magnetic moment is switched into another direction.

In control of the temperature, specifically, along the direction of the current I, a region 1101 at one end of the magnetoresistive tunnel junction 110 may be heated to cause the temperature difference between the one end 1101 of the magnetoresistive tunnel junction and the another end 1102 of the magnetoresistive tunnel junction. A heating manner may be, for example, Joule heating or laser heating. The Joule heating is heating by heat generated by a current flowing through a conductor. The laser heating is heating by a thermal effect generated by high energy of a laser beam on an irradiated surface. It should be understood that neither duration nor temperature of the heating can cause a magnetic change permanently. The magnetic moment is switched only when the temperature difference reaches the certain value. After the heating is stopped, the temperature difference that can cause the switching is decreased, and magnetism returns to a state before the heating.

Hereinabove the technical solutions and technical effects of the spin-orbit torque magnetoresistive random access memory according to the embodiments of the present disclosure are described in detail. Furthermore, according to another aspect of the present disclosure, a method for writing a spin-orbit torque magnetoresistive random access memory is provided according to the present disclosure. Similar to the aforementioned spin-orbit torque magnetoresistive random access memory, the memory includes a spin-orbit coupling layer, and a magnetoresistive tunnel junction on the spin-orbit coupling layer. The magnetoresistive tunnel junction includes a first magnetic layer, a tunneling layer, and a second magnetic layer, which are stacked in sequence from bottom to top. The first magnetic layer and the second magnetic layer are anisotropic in a vertical direction. The method includes: injecting a current to the spin-orbit coupling layer, and controlling a temperature of the magnetoresistive tunnel junction to cause a temperature difference between one end of the magnetoresistive tunnel junction and another end of the magnetoresistive tunnel junction.

According to yet another aspect of the present disclosure, an apparatus for writing a spin-orbit torque magnetoresistive random access memory is provided according to the present disclosure, and is configured to write data into the aforementioned spin-orbit torque magnetoresistive random access memory. Similar to the aforementioned spin-orbit torque magnetoresistive random access memory, the memory includes a spin-orbit coupling layer, and a magnetoresistive tunnel junction on the spin-orbit coupling layer. The magnetoresistive tunnel junction includes a first magnetic layer, a tunneling layer, and a second magnetic layer, which are stacked in sequence from bottom to top. The first magnetic layer and the second magnetic layer are anisotropic in a vertical direction. The writing apparatus includes a current source and a temperature controller.

The current source is configured to inject a current into the spin-orbit coupling layer.

The temperature controller is configured to control a temperature of the magnetoresistive tunnel junction to cause a temperature difference between one end of the magnetoresistive tunnel junction and another end of the magnetoresistive tunnel junction.

The temperature difference is along a direction of the current.

Further, the temperature controller is configured to heat a region at the one end of the magnetoresistive tunnel junction.

Further, the temperature controller is a laser heater or a Joule heater.

The above spin-orbit torque magnetoresistive random access memory can be formed by a suitable method. For the convenience of understanding, the following embodiment for forming the spin-orbit torque magnetoresistive random access memory is described, which is merely as an example. The method for forming the spin-orbit torque magnetoresistive random access memory is not limited in the disclosure.

In a specific embodiment, firstly, the spin-orbit coupling layer 100 made of the metal material, such as Ta and Pt, may be grown by a method of PVD (physical vapor deposition), and may have a thickness of, for example, 3 to 5 nm.

In another embodiment, the spin-orbit coupling layer 100 made of the topological insulator material, such as BiSn and SnTe, may be grown by a method of MBE (molecular beam epitaxy), and may have a thickness of, for example, 3 tol0 nm.

Then, the magnetoresistive tunnel junction 110 is formed on the spin-orbit coupling layer 100.

In a specific embodiment, firstly, the first magnetic layer 102, the tunneling layer 104, the second magnetic layer 106, and the pinning layer 108 are grown in sequence on the spin-orbit coupling layer 100, as shown in FIG. 2.

By sputtering or other suitable methods, the first magnetic layer 102 such as Co/CoFeB, the tunneling layer 104 such as MgO, the second magnetic layer 106 such as Co/CoFeB, and the artificial antiferromagnetic pinning layer 108 such as a CoPt multilayer film may be grown in sequence, and thicknesses thereof may be about 1 nm, 0.8 nm, 1 nm, and 4 to 6 nm, sequentially. Then, the first magnetic layer 102, the tunneling layer 104, the second magnetic layer 106, and the pinning layer 108 are etched until reaching the spin-orbit coupling layer 100, and the magnetoresistive tunnel junction 110 is formed, as shown in FIG. 7.

Thus, the SOT-MRAM according to the embodiment of the present disclosure is formed. Other components such as a protective layer and an electrode may be processed as the requirements.

The foregoing embodiments are only preferred embodiments of the present disclosure. The preferred embodiments according to the disclosure are disclosed above, and are not intended to limit the present disclosure. With the method and technical content disclosed above, those skilled in the art can make some variations and improvements to the technical solutions of the present disclosure, or make some equivalent variations on the embodiments without departing from the scope of technical solutions of the present disclosure. All simple modifications, equivalent variations and improvements made based on the technical essence of the present disclosure without departing the content of the technical solutions of the present disclosure fall within the protection scope of the technical solutions of the present disclosure.

1. A spin-orbit torque magnetoresistive random access memory, comprising:
a spin-orbit coupling layer;
a magnetoresistive tunnel junction on the spin-orbit coupling layer, wherein the magnetoresistive tunnel junction comprises a first magnetic layer, a tunneling layer, and a second magnetic layer, which are stacked in sequence from bottom to top, and the first magnetic layer and the second magnetic layer have the perpendicular magnetic anisotropy;
wherein for data writing of the memory, a current is injected into the spin-orbit coupling layer, and a temperature of the magnetoresistive tunnel junction is controlled to cause a temperature difference between one end of the magnetoresistive tunnel junction and another end of the magnetoresistive tunnel junction.

2. The memory according to claim 1, wherein the temperature difference is along a direction of the current.

3. The memory according to claim 1, wherein the spin-orbit coupling layer is a metal layer, an antiferromagnetic layer or a topological insulator layer.

4. The memory according to claim 3, wherein the metal layer is made of Ta, Pt, W, Hf, Ir, CuBi, CuIr or AuW.

5. The memory according to claim 1, wherein the first magnetic layer and the second magnetic layer are made of Co, Fe, CoPd, FePd, MnGa, CoFeB or FePt.

6. The memory according to claim 1, wherein that the temperature of the magnetoresistive tunnel junction is controlled to cause the temperature difference between the one end of the magnetoresistive tunnel junction and the another end of the magnetoresistive tunnel junction, comprises:
heating a region at the one end of the magnetoresistive tunnel junction, to cause the temperature difference between the one end of the magnetoresistive tunnel junction and the another end of the magnetoresistive tunnel junction.

7. The memory according to claim 6, wherein a manner of the heating is Joule heating or laser heating.

8. A method for writing a spin-orbit torque magnetoresistive random access memory, wherein the memory comprises a spin-orbit coupling layer, and a magnetoresistive tunnel junction on the spin-orbit coupling layer; wherein the magnetoresistive tunnel junction comprises a first magnetic layer, a tunneling layer, and a second magnetic layer, which are stacked in sequence from bottom to top, and the first magnetic layer and the second magnetic layer have perpendicular magnetic anisotropy; and wherein the method comprises:
injecting a current into the spin-orbit coupling layer, and controlling a temperature of the magnetoresistive tunnel junction to cause a temperature difference between one end of the magnetoresistive tunnel junction and another end of the magnetoresistive tunnel junction along a direction of the current.

9. An apparatus for writing the spin-orbit torque magnetoresistive random access memory, wherein the memory comprises a spin-orbit coupling layer, and a magnetoresistive tunnel junction on the spin-orbit coupling layer; wherein the magnetoresistive tunnel junction comprises a first magnetic layer, a tunneling layer, and a second magnetic layer, which are stacked in sequence from bottom to top, and the first magnetic layer and the second magnetic layer have perpendicular magnetic anisotropy; and wherein the apparatus comprises:
a current source, configured to inject a current into the spin-orbit coupling layer; and
a temperature controller, configured to control the temperature of the magnetoresistive tunnel junction to cause a temperature difference between one end of the magnetoresistive tunnel junction and another end of the magnetoresistive tunnel junction.

10. The apparatus according to claim 9, wherein the temperature difference is along a direction of the current.

11. The apparatus according to claim 9, wherein the temperature controller is configured to heat a region at the one end of the magnetoresistive tunnel junction.

12. The apparatus according to claim 11, wherein the temperature controller is a laser heater or a Joule heater.

13. The apparatus according to claim 12, wherein magnetism of each layer changes for a period of time due to the temperature difference, and the magnetism returns to an initial state in a case that the temperature difference is decreased.

14. The memory according to claim 2, wherein that the temperature of the magnetoresistive tunnel junction is controlled to cause the temperature difference between the one end of the magnetoresistive tunnel junction and the another end of the magnetoresistive tunnel junction, comprises:
heating a region at the one end of the magnetoresistive tunnel junction, to cause the temperature difference between the one end of the magnetoresistive tunnel junction and the another end of the magnetoresistive tunnel junction.

15. The memory according to claim 3, wherein that the temperature of the magnetoresistive tunnel junction is controlled to cause the temperature difference between the one end of the magnetoresistive tunnel junction and the another end of the magnetoresistive tunnel junction, comprises:
heating a region at the one end of the magnetoresistive tunnel junction, to cause the temperature difference between the one end of the magnetoresistive tunnel junction and the another end of the magnetoresistive tunnel junction.

16. The memory according to claim 4, wherein that the temperature of the magnetoresistive tunnel junction is controlled to cause the temperature difference between the one end of the magnetoresistive tunnel junction and the another end of the magnetoresistive tunnel junction, comprises:
heating a region at the one end of the magnetoresistive tunnel junction, to cause the temperature difference between the one end of the magnetoresistive tunnel junction and the another end of the magnetoresistive tunnel junction.

17. The memory according to claim 5, wherein that the temperature of the magnetoresistive tunnel junction is controlled to cause the temperature difference between the one end of the magnetoresistive tunnel junction and the another end of the magnetoresistive tunnel junction, comprises:
heating a region at the one end of the magnetoresistive tunnel junction, to cause the temperature difference between the one end of the magnetoresistive tunnel junction and the another end of the magnetoresistive tunnel junction.
